(19) United States
(12) Patent Application Publication
(10) Pub. No.: US 2026/0314465 A1
(43) Pub. Date: Oct. 8, 2026

(54) POWER ELECTRONICS MODULE AND INVERTER INCLUDING A POWER ELECTRONICS MODULE

(71) Applicant: Schaeffler Technologies AG & Co. KG, Herzogenaurach (DE)

(72) Inventors: Markus Hövermann, Rückersdorf (DE); Michael Haber, Berlin (DE); Peter Krasselt, Heroldsberg (DE); Andreas Mühlbauer, Bernhardswald (DE); Martin Ehrmann, Nürnberg (DE)

(73) Assignee: Schaeffler Technologies AG & Co. KG, Herzogenaurach (DE)

(21) Appl. No.: 18/998,595

(22) PCT Filed: Jul. 27, 2023
(86) PCT No.: PCT/EP2023/070815

§ 371 Date: Jan. 27, 2025

(30) Foreign Application Priority Data
Jul. 29, 2022 (DE) 10 2022 207 850.0

(51) Int. Cl. H10W 72/60; H02M 7/00; H10D 80/20; H10W 40/25; H10W 72/00; H10W 90/00; H10W 90/10

(52) U.S. Cl. CPC H10W 72/642; H10W 40/255; H10W 72/871; H10W 90/10; H10W 90/754; H10W 90/764; H02M 7/003; H10D 80/251

(57) ABSTRACT

A power electronics module, having a first current connection area in a first electrical contact plane of the module; a second current connection area in a second electrical contact plane of the module; a first plate-shaped contact-making element formed in one piece and having a first contact-making portion, which is contact-connected to the first current connection area, a second contact-making portion, which is contact-connected to the second current connection area, and two connecting portions, which each extend from the first to the second contact-making portion of the first contact-making element. A recess is provided in the first contact-making element between the connecting portions of the first contact-making element, the recess forming an intermediate space in the first contact-making element. A first signal connecting element is passed through the intermediate space in the first contact-making element.

### CROSS-REFERENCE TO RELATED APPLICATIONS

This application claims priority £ to PCT Application PCT/EP2023/070815, filed Jul. 27, 2023, which claims priority to German Patent Application No. DE 10 2022 207 850.0, filed Jul. 29, 2022. The disclosures of the above applications are incorporated herein by reference.

### FIELD OF THE INVENTION

The present invention relates to a power electronics module for a converter, such as, for example, an inverter or a DC-DC converter, specifically for an electric drive of a motor vehicle. The invention also relates to an inverter, for an electric drive of a motor vehicle.

### BACKGROUND OF THE INVENTION

Converters, such as inverters or DC-DC converters, for converting an input electric current of one current type (direct current, alternating current) into a current of another current type (alternating current, direct current) or for changing characteristic parameters, such as the voltage, of an input current, are known and are used, inter alia, in electric drive devices of motor vehicles. Power electronics modules, which carry out the task of current/voltage conversion, form essential components of these converters. In this case, the power electronics modules generally form switchable half-bridges of the converters.

As is customary in all technical apparatuses, there is also the general requirement for the converters to be constructed in a space-saving manner.

### SUMMARY OF THE INVENTION

It is thus the object of the present application to provide a possibility of reducing the size of a power electronics module and thus of a converter with a constant or even a higher power requirement in the converter.

This object is achieved by the subjects described.

A first aspect of the invention provides a power electronics module for a converter, such as, for example, an inverter or a DC-DC converter.

The power electronics module has a first current connection area located in a first electrical contact plane of the module and a second current connection area located in a second electrical contact plane of the module.

The power electronics module furthermore has a first electrical contact-making element which is formed in one piece in the form of a plate. The first contact-making element has a first contact-making portion, which rests on the first current connection area and is physically and electrically contact-connected or connected to the first current connection area, and a second contact-making portion, which rests on the second current connection area and is physically and electrically contact-connected or connected to the second current connection area. In this case, the two contact-making portions are formed opposite one another, as viewed in the longitudinal direction of the first contact-making element.

The first contact-making element furthermore has two (longitudinal) connecting portions, which each extend (next to one another in the longitudinal direction of the first contact-making element, for example parallel to one another) from the first contact-making portion to the second contact-making portion of the first contact-making element and, similarly to connecting webs, connect the two contact-making portions (right and left of the respective contact-making portions) to one another in one piece.

Between the two connecting portions, the first contact-making element furthermore has a recess, which forms an intermediate space in the first contact-making element. In this case, the two contact-making portions and the two connecting portions of the first contact-making element surround the intermediate space in the first contact-making element at least partially, in an embodiment virtually completely, and in another embodiment specifically completely.

The power electronics module also has a first signal connecting element, which is passed through the intermediate space in the first contact-making element.

In this case, the first contact-making element is formed in one piece in the form of a plate. The expression “in the form of a plate” here means that the contact-making element is formed from a hard, electrically conductive material, such as sheet metal, for example, with its own mechanical stiffness or strength and is thus able to withstand a certain mechanical stress without a mechanical carrier. Accordingly, the first contact-making element is not a conventional conductor track of a printed circuit board, which essentially does not have its own mechanical stiffness and is therefore reliant on the printed circuit board.

By virtue of the fact that the first contact-making element, owing to its specific shape, enables a current connection between current connection areas in two different contact planes (at different structural heights) of the power electronics module with the contact-making portions and the connecting portions connecting the two contact-making portions in one piece to one another, and, moreover, a signal connection between signal connection areas in two (additional) different contact planes through the intermediate space thereof (at different structural heights) of the power electronics module, the current or signal connection areas of the power module may be designed to be distributed over different structural heights of the power module. Accordingly, it is possible to avoid the connection areas and thus also the current-carrying or signal-carrying components having to be installed on one plane. This in turn makes it possible to avoid complex interconnection of these components using numerous bonding connections. In this case, the first contact-making element already replaces first bonding connections, which would otherwise be necessary for the current connection between the current connection areas. The remaining signal connection through the intermediate space of the first contact-making element is established using one or a few bonding connections. Thanks to the position that is spatially protected by the first contact-making element, the signal connection is also not susceptible to external interference. As a result of the reduction in the number of bonding connections, which have relatively high space requirements, the structural height of the construction of the module is also reduced overall, despite the design of the current/signal connection areas on different contact planes.

Consequently, a more compact design of the power module is achieved with a small size compared to a module with current-carrying or signal-carrying components on a plane or current/signal connection areas on a contact plane.

The current connection via the first contact-making element and the signal connection through the intermediate space at the first contact-making element is implemented with a sufficient physical distance and thus a sufficient insulation distance, which has a positive effect on the parasitic inductance in the module.

The above-described solution enables the use of compact and high-performance semiconductors, which may be silicon carbide semiconductors, such as silicon carbide MOSFETs, and thus further miniaturization of the current-carrying components in the power electronics module and thus a reduction in the size of the power electronics module itself. In this case, the first contact-making element may be contact-connected directly to the silicon carbide semiconductors and other current-carrying components, for example by soldering or sintering.

This provides the possibility of reducing the size of a power electronics module and thus of a converter with a constant or even a higher power requirement in the converter.

For example, the power electronics module furthermore has a first signal connection area and a second signal connection area. The first signal connection area lies in the first contact plane. The second signal connection area lies in a third contact plane of the module. In this case, the first, the second and the third contact plane of the module lie at different structural heights of the module, wherein the second contact plane lies between the first and the third contact plane. The first signal connecting element electrically connects the first signal connection area to the second signal connection area.

The first signal connecting element thus bridges the height difference between the first and the third contact plane and connects the first and the second signal connection area over the shortest connecting path through the intermediate space of the first contact-making element.

For example, the first contact-making element is formed as a stamped and bent part that is bent from the first contact plane toward the second contact plane. The first contact-making element thus overcomes the height difference between the first and the second contact plane.

In this case, the first contact-making element may be made of a plate-shaped metal part or sheet metal, specifically of a plate-shaped copper part or a copper sheet, in separating and forming processes such as stamping, fine cutting, etching, laser treatment, etc. and subsequent bending and/or calibration in a simple manner and, in the process, may also be dimensioned to be flexible in accordance with the shape and the requirement. Furthermore, additional regions may be formed in the contact-making element, for example regions for increasing the strength or openings (or additional intermediate spaces) for leading through additional signal connections.

For example, the first contact-making element has, on the first contact-making portion, at least one connection lug that is bent away from the main plane of the first contact-making portion in the direction of the first contact plane. As an alternative or in addition thereto, the first contact-making element may have, on the second contact-making portion, at least one additional connection lug that is bent away from the main plane of the second contact-making portion in the direction of the second contact plane. The connection lugs make it possible for the first contact-making element to further overcome the height difference between the first and the second contact plane.

The power electronics module also has, for example, a third current connection area which lies in the second contact plane.

In addition, the power electronics module has, for example, a second electrical contact-making element, which is formed in one piece in the form of a plate. The second contact-making element has a first contact-making portion, which rests on the third current connection area and is physically and electrically contact-connected or connected to the third current connection area, and a second contact-making portion, which is in the form of a first external current connection of the power electronics module and is set up to electrically connect the power electronics module to a first external current connection. In this case, the two contact-making portions are formed opposite one another, as viewed in the longitudinal direction of the second contact-making element. The second contact-making element furthermore has two (longitudinal) connecting portions, which each extend (next to one another in the longitudinal direction of the second contact-making element, parallel to one another) from the first contact-making portion to the second contact-making portion of the second contact-making element and, similarly to connecting webs, connect the two contact-making portions (more specifically corresponding edge regions of the respective contact-making portions in pairs) to one another in one piece. Between the two connecting portions, the second contact-making element furthermore has a recess, which forms an intermediate space in the second contact-making element. In this case, the two contact-making portions and the two connecting portions of the second contact-making element surround the intermediate space in the second contact-making element at least partially, in an embodiment virtually completely, and in another embodiment specifically completely.

In this case, the first signal connecting element is guided through the intermediate space in the second contact-making element.

The second contact-making element is formed in one piece in the form of a plate, such as from an additional plate-shaped metal part or additional sheet metal, specifically from an additional plate-shaped copper part or additional copper sheet.

For example, the first contact-making portion of the second contact-making element has at least one connection lug that is bent away from the main plane of the second contact-making element of the second contact-making element in the direction of the second contact plane.

For example, the power electronics module also has at least one electrically insulating plastic compound which is formed from an electrically insulating and thermally conductive material. In addition, the power electronics module has, for example, at least one first small metal plate, which is at least partially embedded in the plastic compound and has an exposed surface. In this case, at least part of the surface of the first small metal plate forms the second signal connection area of the power electronics module.

By way of example, the first signal connecting element is formed as a bonding wire or a bonding tape.

By way of example, the power electronics module also has a third signal connection area which lies in the third contact plane of the module. In addition, the power electronics module has a fourth signal connection area, for example, on a surface of the first contact-making element facing away from the first current connection area (or on a surface of the first contact-making portion of the first contact-making element facing away from the first current connection area). In addition, the power electronics module has a second signal connecting element, which is passed through the intermediate space in the second contact-making element and electrically connects the fourth signal connection area to the third signal connection area.

For example, the power electronics module also has at least one second small metal plate, which is at least partially embedded in the plastic compound and has an exposed surface. In this case, at least part of the surface of the second small metal plate forms the third signal connection area of the power electronics module.

For example, the power electronics module also has at least one additional signal connection area in the second contact plane of the module and at least one additional signal connection area in the third contact plane of the module. In addition, the power electronics module has, for example, at least one additional signal connecting element, which is passed through the intermediate space in the second contact-making element and electrically connects the aforementioned additional signal connection area in the second contact plane to the aforementioned additional signal connection area in the third contact plane.

By way of example, the power electronics module also has a circuit carrier which has a first conductor track and a second conductor track on the same surface or on the same placement side. In this case, a part of the first conductor track forms the first current connection area of the power electronics module. The power electronics module additionally has, for example, a first semiconductor switch which has a first load current connection on its first surface and a second load current connection on its second surface facing away from the first surface. The first semiconductor switch rests on the second conductor track and is physically and electrically contact-connected or connected to the second conductor track via the first load current connection. The second load current connection of the first semiconductor switch forms the second current connection area of the power electronics module. The first contact-making element thus electrically connects the first conductor track to the second load current connection of the first semiconductor switch.

For example, a part of the second conductor track forms the first signal connection area. In this case, the first signal connecting element electrically connects the second conductor track to the first small metal plate.

The power electronics module also has, for example, a second semiconductor switch which has a first load current connection on its first surface and a second load current connection on its second surface facing away from the first surface. The second semiconductor switch rests on the first conductor track and is physically and electrically contact-connected or connected to the first conductor track via the first load current connection. The second load current connection of the second semiconductor switch forms the third current connection area of the power electronics module.

The semiconductor switches may be in the form of transistors based on silicon carbide or gallium nitride, such as SiC MOSFETs (silicon carbide metal oxide field-effect transistor) or GaN MOSFETs (gallium nitride metal oxide field-effect transistor). As an alternative, the semiconductor switches may be in the form of field-effect transistors based on beta-Ga2O3 (beta-gallium oxide). It is also possible for the semiconductor switches to be in the form of Si-IGBTs, that is to say silicon-based IGBTs (silicon-carbide insulated-gate bipolar transistor).

By way of example, the power electronics module also has a third electrical contact-making element which is formed in one piece in the form of a plate and which rests on the second conductor track and is physically and electrically contact-connected or connected to the second conductor track. The third contact-making element is for example in the form of a third plate-shaped metal or copper part or a third metal or copper sheet. The power electronics module additionally has, for example, a plate-shaped electrical insulator, which is arranged between the second and the third contact-making element and is physically and thermally connected to the second and the third contact-making element. The insulator physically connects the second and the third contact-making element to one another and at the same time electrically insulates the two contact-making elements from one another.

By way of example, the insulator is part of the aforementioned plastic compound.

By way of example, the power electronics module also has a fourth electrical contact-making element which is formed in one piece and in the form of a plate and which rests on the first conductor track and is physically and electrically contact-connected or connected to the first conductor track. The fourth contact-making element is for example in the form of a fourth plate-shaped metal or copper part or a fourth metal or copper sheet.

For example, the circuit carrier has, on an additional surface facing away from the conductor tracks, a (for example metallic) cooling layer for cooling the power electronics module.

A first aspect of the invention provides an inverter, specifically for an electric drive of a motor vehicle.

The inverter has a housing and a number of previously described power electronics modules arranged in the housing.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

Exemplary embodiments of the invention are explained in more detail below with reference to the accompanying drawings. In the drawings:

FIG. 1 shows a schematic plan view illustration of a contact-making element of a power electronics module according to an exemplary embodiment of the invention;

FIG. 2 shows another schematic plan view illustration of an additional contact-making element of a power electronics module according to another exemplary embodiment of the invention;

FIG. 3 shows another schematic plan view illustration of a power electronics module according to an exemplary embodiment of the invention with the contact-making elements from FIGS. 1 and 2; and

FIG. 4 shows a schematic cross-sectional illustration of the module from FIG. 3.

### DETAILED DESCRIPTION OF THE PREFERRED EMBODIMENTS

The following description of the preferred embodiment(s) is merely exemplary in nature and is in no way intended to limit the invention, its application, or uses.

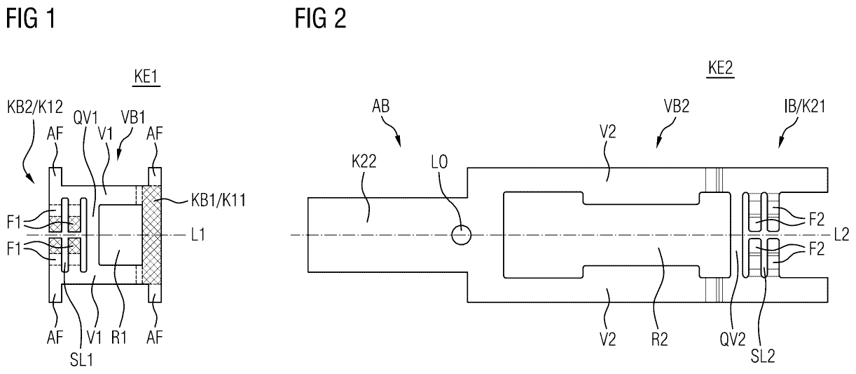

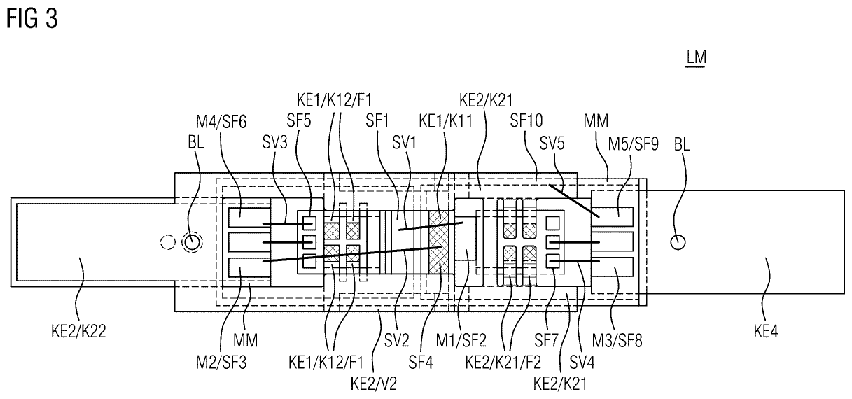

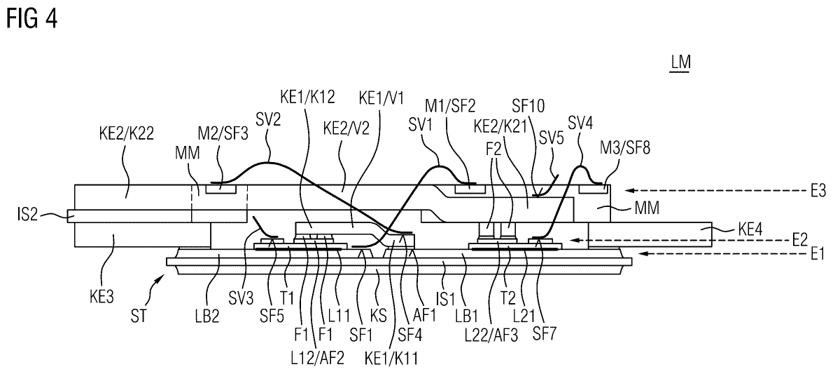

FIG. 1 shows a schematic plan view illustration of a first contact-making element KE1 according to an exemplary embodiment of the invention, which is inserted as a first contact-making element into a power electronics module LM from FIGS. 3 and 4.

The first contact-making element KE1 is stamped and bent in a corresponding shape from a copper sheet (of high-purity copper or a copper alloy) as a stamped and bent part formed in one piece. In this case, the first contact-making element KE1 is shaped symmetrically about the longitudinal axis L1 thereof.

The first contact-making element KE1 is divided into a first contact region KB1 with a first contact-making portion K11, a second contact region KB2 with a second contact-making portion K12 which, as viewed in the direction of extent of the longitudinal axis L1 of the contact-making element KE1, lies facing away from the first contact region KB1, and also a connecting region VB1 with two connecting strips or two connecting portions V1, which is situated between the two contact regions KB1, KB2 and connects the two regions KB1, KB2 to one another in one piece.

The first contact region KB1 or the first contact-making portion K11 is of strip-shaped form and extends transversely to the direction of extent of the longitudinal axis L1 of the contact-making element KE1.

The two connecting strips V1 of the connecting region VB1 are shaped substantially symmetrically with respect to one another and extend in a limb-like manner in each case from one of the two end regions of the first contact-making portion K11 along the direction of extent of the longitudinal axis L1 in the direction of the second contact region KB2 and connect the second contact region KB2 to the first contact-making portion K11 in one piece. In this case, the two connecting portions V1 are bent from the main plane of the first contact-making portion K11 in the direction of the main plane of the second contact region KB2 and thus bridge the height difference between the main planes of the contact regions KB1, KB2. Furthermore, the two connecting portions V1 bridge the longitudinal distance along the longitudinal axis L1 between the two contact-making portions K11, K12.

In a subregion adjoining the second contact region KB2, the connecting region VB1 has a transverse connecting web QV1 which extends transversely to the direction of extent of the longitudinal axis L1 of the first contact-making element KE1 and which connects the two connecting portions V1 to one another at their respective sub-portions adjoining the second contact region KB2. The transverse connecting web QV1 primarily serves for mechanically stabilizing the connecting region VB1 and thus for increasing the mechanical strength of the first contact-making element KE1.

The first contact-making element KE1 has a recess which is completely bordered by the two contact regions KB1, KB2 and the connecting region VB1 or by the first contact-making portion K11 and the two connecting portions V1 together with the transverse connecting web QV1 and thus forms a bordered intermediate space R1 extending through the first contact-making element KE1. The mode of operation of the intermediate space R1 is described in more detail below on the basis of FIGS. 3 and 4.

The second contact region KB2 or the second contact-making portion K22 has four connection lugs F1, which are formed in pairs distributed on each one of the two connection portions V1 in a manner similar to prongs of a fork and each extend parallel to one another in the direction of the longitudinal axis L1 of the first contact-making element KE1. Between the four connection lugs F1, the second contact region KB2 has slots SL1 which, in plan view of the first contact-making element KE1, form a cross shape and physically separate the four connection lugs F1 from one another at their exposed ends, such that the four connection lugs F1 do not touch one another. In this case, the connection lugs F1 are bent away from the main plane of the second contact region KB2 or the second contact-making portion K22, as illustrated in FIG. 4.

The first contact-making element KE1 in plan view has a substantially quadrilateral shape. At four corner regions, the contact-making element KE1 has a respective projecting (positioning) molding AF, via which the contact-making element KE1 is held by an appropriate carrier tool in subsequent assembly steps, such as, for example, during soldering or sintering of the contact-making element KE1 onto a circuit carrier or a semiconductor, and is positioned in a corresponding assembly position.

FIG. 2 shows another schematic plan view illustration of a second contact-making element KE2 according to another exemplary embodiment of the invention, which is inserted as a second contact-making element into the power electronics module LM from FIGS. 3 and 4.

The second contact-making element KE2 is likewise stamped and bent in a corresponding shape as a stamped and bent part formed in one piece from a copper sheet (of high-purity copper or a copper alloy). In this case, the second contact-making element KE2 is shaped symmetrically about the longitudinal axis L2 thereof.

The second contact-making element KE2 is divided into an inner contact region IB with a first contact-making portion K21, via which the contact-making element KE2 is electrically connected inside the power electronics module, an outer contact region AB with a second contact-making portion K22, which lies facing away from the inner contact region IB as viewed in the direction of extent of the longitudinal axis L2 of the contact-making element KE2 and via which the contact-making element KE2 or the power electronics module LM is electrically connected externally, and a connecting region VB2 with two connecting portions V2, which is situated between the inner contact region IB and the outer region AB and connects the two regions IB, AB to one another in one piece.

In plan view of the second contact-making element KE2, the outer contact region AB or the second contact-making portion K22 is of substantially rectangular shape and accordingly has a rectangular, areally extended contact surface which serves for electrically contact-connecting the second contact-making element KE2 and thus the module LM to an external electrical component. The second contact-making portion K22 also has one or more (positioning) holes or bores LO which pass through the second contact-making portion K22 and via which the contact-making element KE2 is held by an appropriate carrier tool in subsequent assembly steps, such as, for example, during soldering or sintering of the contact-making element KE2 onto a circuit carrier, and is positioned in a corresponding assembly position.

The two connecting portions V2 are shaped substantially symmetrically with respect to one another and extend in a limb-like manner from the outer contact region AB or from the second contact-making portion K22 in the direction of extent of the longitudinal axis L2 of the contact-making element KE2 toward the inner contact region IB. The outer contact region AB and the connecting region VB2 or the second contact-making portion K22 and the two connecting portions V2 thus essentially have the shape of a tuning fork. The two connecting portions V2 connect the outer contact region AB to the inner contact region IB adjoining the connection region VB2 in the direction of extent of the longitudinal axis L2 of the contact-making element KE2. In this case, the two connecting portions V2 are bent from the main plane of the outer contact region AB in the direction of the main plane of the inner contact region IB and thus bridge the height difference between the main planes of the outer and inner contact regions AB, IB. Furthermore, the two connecting portions V2 bridge the longitudinal distance along the longitudinal axis L2 between the two contact-making portions K21, K22.

In a subregion adjoining the inner contact region IB, the connecting region VB2 has a transverse connecting web QV2 which extends transversely to the direction of extent of the longitudinal axis L2 of the second contact-making element KE2 and which connects the two connecting portions V2 to one another at their respective sub-portions adjoining the inner contact region IB. The transverse connecting web QV2 primarily serves for mechanically stabilizing the connecting region VB2 and thus for increasing the mechanical strength of the second contact-making element KE2.

The second contact-making element KE2 has a recess which is completely bordered by the outer contact, connecting and inner contact regions AB, VB2 and IB and by the second contact-making portion K22, the two connecting portions V2 together with the transverse connecting web QV2 and thus forms a bordered intermediate space R2 extending through the second contact-making element KE2. The mode of operation of the intermediate space R2 is described in more detail below on the basis of FIGS. 3 and 4.

The inner contact region IB or the first contact-making portion K21 has four connection lugs F2, which are formed in pairs distributed on each one of the two connecting portions V2 in a manner similar to prongs of a fork and each extend parallel to one another in the direction of the longitudinal axis L2 of the second contact-making element KE2. In this case, connection lugs F2 are formed in pairs symmetrically with respect to the longitudinal axis L2. Between the four connection lugs F2, the first contact-making portion K21 has slots SL2 which, in plan view of the second contact-making element KE2, form a cross shape and physically separate the four connection lugs F2 from one another at their exposed ends, such that the four connection lugs F2 do not touch one another. In this case, the connection lugs F2 are bent away from the main plane of the first contact-making portion K21 in a direction away from the main plane of the second contact-making portion K22, as illustrated in FIG. 4.

FIGS. 3 and 4 each show a schematic plan view illustration or a schematic cross-sectional illustration of a power electronics module LM according to an exemplary embodiment of the invention having the two contact-making elements KE1, KE2 from FIGS. 1 and 2.

The power electronics module LM forms a switchable half-bridge circuit with two series-connected semiconductor switches T1, T2 and has a circuit carrier ST which is formed from a DCB (direct copper bonded) substrate or an AMB (active metal brazed) substrate and on which the half-bridge circuit is formed.

The circuit carrier ST has an electrically insulating (ceramic) insulating layer IS1, and a first and a second conductor track LB1, LB2, which are formed next to one another in a manner extending areally on the same surface of the insulating layer IS1. On a surface of the insulating layer IS1 facing away from the conductor tracks LB1, LB2, the circuit carrier ST has an areally extended cooling layer KS for cooling the module LM.

The two conductor tracks LB1, LB2 or their respective surfaces facing away from the insulating layer IS1 are situated in a first contact plane E1 of the power electronics module LM or form the first contact plane E1.

The power electronics module LM also has a first and a second semiconductor switch T1, T2 in the form of a SIC MOSFET without a housing (as bare chips) in this embodiment. The first semiconductor switch T1 is placed centrally on the second conductor track LB2 and is sintered or soldered onto the second conductor track LB2 via its first load current connection L11 (drain connection) formed on the underside thereof. Analogously, the second semiconductor switch T2 is placed centrally on the first conductor track LB1 and is sintered or soldered onto the first conductor track LB1 via its first load current connection L21 (drain connection) formed on the underside thereof. The two semiconductor switches T1, T2 each have on their respective top sides a second, top-side load current connection L12, L22 (source connection) and a plurality of top-side signal connections (gate and kelvin source connection).

The second, top-side load current connections L12, L22 or their respective current connection areas AF2, AF3, and the respective top-side signal connections or their respective signal connection areas SF5, SF7 are located in a second contact plane E2 of the power electronics module LM or form the second contact plane E2. In this case, the above-described first contact plane E1 and the second contact plane E2 lie at different structural heights of the module LM, as is illustrated in FIG. 4.

The power electronics module LM also has the first contact-making element KE1 described above on the basis of FIG. 1, the second contact-making element KE2 described above on the basis of FIG. 2, and also a third and a fourth contact-making element KE3, KE4. In this case, the third and the fourth contact-making element KE3, KE4 are also stamped in a corresponding shape from a copper sheet (of high-purity copper or a copper alloy) as a stamped part formed in one piece.

The third contact-making element KE3 is placed, via its right-hand end region (as viewed in FIG. 4), on a left-hand edge region (as viewed in FIG. 4) of the second conductor track LB2 next to the first semiconductor switch T1 and is electrically contact-connected to the second conductor track LB2. In this case, the third contact-making element KE3 is sintered or soldered onto the second conductor track LB2.

The first contact-making element KE1 rests via its first contact-making portion K11 on a right-side edge region (as viewed in FIG. 4) (or on the first current connection area AF1 thereof) of the first conductor track LB1 next to the second semiconductor switch T2 and is electrically contact-connected to the first conductor track LB1. In this case, the first contact-making element KE1 or the first contact-making portion K11 thereof is sintered or soldered onto the first conductor track LB1. Via its second contact-making portion K12 or its four connection lugs F1, the first contact-making element KE1 rests on the first semiconductor switch T1 and is electrically contact-connected to its second load current connection L12. In this case, the second contact-making portion K12 or the four connection lugs F1 are sintered or soldered onto the second load current connection L12. Thanks to the connecting portions V1 which are bent from the main plane of the first contact-making portion K11 toward the main plane of the second contact-making portion K12, the first contact-making element KE1 bridges the height difference between the first and the second contact plane E1, E2.

The second contact-making element KE2 rests via its first contact-making portion K21 or its four connection lugs F2 on the second semiconductor switch T2 and is electrically contact-connected to its second load current connection L22. In this case, the first contact-making portion K21 or the four connection lugs F2 are sintered or soldered onto the second load current connection L22. The second contact-making element KE2 rests indirectly via its second contact-making portion K22 on the third contact-making element KE3. Arranged between the second and the third contact-making element KE2, KE3 is a plate-shaped electrical insulator IS2, which physically connects the second and the third contact-making element KE2, KE3 to one another and at the same time electrically insulates them from one another. In this case, the insulator IS2 is part of a plastic compound MM (for example from a mold compound) to be described below. Thanks to the connecting portions V2 bent from the main plane of the first contact-making portion K21 toward the main plane of the second contact-making portion K22 and the connection lugs F2 projecting from the main plane of the first contact-making portion K21 in the direction of the second semiconductor switch T2, the second contact-making element KE2 bridges the height difference between the second contact plane E2 and the main plane of the second contact-making portion K22.

The fourth contact-making element KE4 is placed, via its left-hand end region (as viewed in FIG. 4), on a right-hand edge region (as viewed in FIG. 4) of the first conductor track LB1 next to the second semiconductor switch T2 and is electrically contact-connected to the first conductor track LB1. In this case, the fourth contact-making element KE4 is sintered or soldered onto the first conductor track LB1.

The power electronics module LM additionally has the aforementioned plastic compound MM composed of an electrically insulating and thermally conductive plastic, which is formed in one piece or in multiple pieces in cavities on or between the contact-making elements KE1, KE2, KE3, KE4. On a surface facing away from the circuit carrier ST, the plastic compound MM has a plurality of small metal or copper plates M1, M2, M3, M4, M5 each having a signal connection area SF2, SF3, SF8, SF6, SF9, which are encapsulated by the plastic compound MM except for their respective signal connection area. The small copper plates M1, M2, M3, M4, M5 or their signal connection areas SF2, SF3, SF8, SF6, SF9 are used to establish signal connections between the two semiconductor switches T1, T2 on the one hand and an external driver/control circuit (not illustrated in the figures) of the power module LM.

Additional signal connections may be provided for transmitting sensor or control signals (also for further circuit components), which for example are formed in the manner of bonding wires and are guided through the intermediate spaces R1, R2 in the first and/or in the second contact-making element KE1, KE2. Analogously, it is also possible to provide fewer signal connections than described above, depending on requirements.

The small copper plates M1, M2, M3, M4, M5 or their signal connection areas SF2, SF3, SF8, SF6, SF9 are situated in a third contact plane E3 of the power electronics module LM or form the third contact plane E3. In this case, the third contact plane E3 lies between the above-described first and the above-described second contact plane E1, E2 and thus at different structural heights to the two contact planes E1, E2.

The power electronics module LM also has a plurality of signal connecting elements SV1, SV2, SV3, SV4, SV5, which are formed from bonding wires or bonding tapes.

A first signal connecting element SV1 electrically connects a first signal connection area SF1, which is part of the second conductor track LB2 and thus lies in the first contact plane E1, to a second signal connection area SF2, which is formed on a first small copper plate M1 and lies in the third contact plane E3 of the module LM. The first signal connecting element SV1 thus bridges the height difference between the first and the third contact plane E1, E3. In this case, the first signal connecting element SV1 is led through the intermediate spaces R1, R2 in the first and the second contact-making element KE1, KE2, respectively.

A second signal connecting element SV2 electrically connects the first contact-making portion K11 of the first contact-making element KE1 or a signal connection area SF4 on a surface of the contact-making portion K11 facing away from the first current connection area AF1 to a third signal connection area SF3, which is formed on a second small copper plate M2 and lies in the third contact plane E3 of the module LM. The first signal connecting element SV1 thus bridges the height difference between the first contact-making element KE1 and the third contact plane E3. In this case, the second signal connecting element SV2 is passed through the intermediate space R2 in the second contact-making element KE2.

A third signal connecting element SV3 electrically connects a fifth signal connection area SF5, which is formed on a signal connection of the first semiconductor switch T1 and thus lies in the second contact plane E2, to a sixth signal connection area SF6, which is formed on an additional small copper plate and thus lies in the third contact plane E3. In this case, the third signal connecting element SV3 is led through the intermediate space R2 in the second contact-making element KE2 and bridges the height difference between the two contact planes E2, E3.

A fourth signal connecting element SV4 electrically connects a seventh signal connection area SF7, which is formed on a signal connection of the second semiconductor switch T2 and thus lies in the second contact plane E2, to an eighth signal connection area SF8, which is formed on an additional small copper plate M3 and thus lies in the third contact plane E3. In this case, the fourth signal connecting element SV4 likewise bridges the height difference between the two contact planes E2, E3.

A fifth signal connecting element SV5 electrically connects a ninth signal connection area SF9, which is formed on an additional small copper plate M3 and thus lies in the third contact plane E3, to a tenth signal connection area SF10, which is formed on a surface of the second contact-making element KE2 facing away from the circuit carrier ST.

The power module LM is encapsulated by a molding compound, wherein the molding compound fills intermediate spaces between the above-described components of the module LM and mechanically stabilizes same and at the same time electrically insulates them from one another. In this case, exposed ends of the second, third and fourth contact-making element KE2, KE3, KE4 (in each case left-side end regions of the second and third contact-making element KE2, KE3 and right-side end region of the fourth contact-making element KE4) project out of the molding compound. These end regions form external current connections (H+ connection, H− connection or phase connection) of the power module LM. The cooling layer KS of the circuit carrier ST is also free from the molding compound. The module LM may be thermally contact-connected to a cooler via the cooling layer KS.

Parasitic inductance is reduced by virtue of the overlapping embodiment of the second and third contact-making element KE2, KE3 over virtually the entire length of the third contact-making element KE3, which form H+/H− connections of the power module LM.

The current conduction via the contact-making elements KE1, KE2, KE3 and KE4 as stamped or stamped and bent parts and the layer-by-layer embodiment of the contact-making elements KE1, KE2, KE3 and KE4 enable current/signal conduction on a plurality of levels E1, E2, E3 and thus a reduction in the area of the circuit carrier ST, associated with a significant reduction in the costs and the module size in the power module LM. In this case, the contact-making elements KE1, KE2, KE3 and KE4 may—unlike clips or stamped and bent parts formed in corrugated fashion—be formed with a sufficiently large cross-sectional area in order to enable high current flows.

The use of the first and second contact-making element KE1, KE2 with the respective intermediate spaces R1, R2 enables space-saving signal connections between different contact planes of the module LM, wherein the connections are guided through the intermediate spaces R1, R2 and thus over short connecting paths from one plane to another plane and are protected from external influences by the two contact-making elements KE1, KE2. The intermediate spaces R1, R2 also enable simple access of bonding tools during the production of the signal connections to the (bonding) connection areas and subsequent optical control of the signal connections. Furthermore, the intermediate spaces R1, R2 prevent the formation of air inclusions during the molding process, in which the power module LM is formed with the aforementioned molding compound.

The description of the invention is merely exemplary in nature and, thus, variations that do not depart from the gist of the invention are intended to be within the scope of the invention. Such variations are not to be regarded as a departure from the spirit and scope of the invention.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. A power electronics module, comprising:
a first current connection area in a first electrical contact plane of the module;
a second current connection area in a second electrical contact plane of the module;
a first plate-shaped contact-making element formed in one piece, further comprising:
a first contact-making portion, which is contact-connected to the first current connection area;
a second contact-making portion, which is contact-connected to the second current connection area;
at least two connecting portions, which each extend from the first contact-making portion to the second contact-making portion of the first plate-shaped contact-making element;
a recess in the first plate-shaped contact-making element between the at least two connecting portions of the first plate-shaped contact-making element, the recess forming an intermediate space in the first plate-shaped contact-making element;
a first signal connecting element, which is passed through the intermediate space in the first plate-shaped contact-making element.

21. The power electronics module of claim 20, wherein
a first signal connection area, which lies in the first electrical contact plane;
a second signal connection area, which lies in a third electrical contact plane of the module, the first signal connecting element connects the first signal connection area to the second signal connection area;
wherein the first electrical contact plane, the second electrical contact plane and the third electrical contact plane lie at different structural heights of the module, and the second electrical contact plane lies between the first electrical contact plane and the third electrical contact plane.

22. The power electronics module of claim 21, further comprising:
a third current connection area in the second electrical contact plane;
a second plate-shaped contact-making element formed in one piece and having
a first electrical contact-making portion, which is contact-connected to the third current connection area;
a second electrical contact-making portion for establishing a first external current connection for the module;
a plurality of connecting portions, which each extend from the first electrical contact-making portion to the second electrical contact-making portion of the second plate-shaped contact-making element;
a recess in the second plate-shaped contact-making element between at least two of the plurality of connecting portions of the second plate-shaped contact-making element, the recess forming a second intermediate space in the second plate-shaped contact-making element;
wherein the first signal connecting element is passed through the second intermediate space in the second plate-shaped contact-making element.

23. The power electronics module of claim 22, the first electrical contact-making portion of the second plate-shaped contact-making element further comprising at least one connection lug that is bent away from the main plane of the second plate-shaped contact-making element in the direction of the second electrical contact plane.

24. The power electronics module of claim 22, further comprising:
an electrically insulating plastic compound;
a first small metal plate, which is at least partially embedded in the plastic compound and has an exposed surface;
wherein the second signal connection area is part of the surface of the first small metal plate.

25. The power electronics module of claim 24, further comprising:
a third signal connection area in the third electrical contact plane of the module;
a fourth signal connection area on a surface of the first plate-shaped contact-making element facing away from the first current connection area;
a second signal connecting element, which is passed through the second intermediate space in the second contact-making element and electrically connects the fourth signal connection area to the third signal connection area.

26. The power electronics module of claim 25, further comprising:
a second small metal plate, which is at least partially embedded in the plastic compound and has an exposed surface;
wherein the third signal connection area is part of the surface of the second small metal plate.

27. The power electronics module of claim 25, further comprising:
at least one additional signal connection area in the second electrical contact plane of the module;
at least one additional signal connection area in the third electrical contact plane of the module; and
at least one additional signal connecting element, which is passed through the second intermediate space in the second plate-shaped contact-making element and electrically connects the signal connection area in the second electrical contact plane to the signal connection area in the third electrical contact plane.

29. The power electronics module of claim 27, further comprising:
a circuit carrier having a first conductor track and a second conductor track on the same placement side, wherein the first current connection area is part of the first conductor track;
a first semiconductor switch having a first load current connection on a first surface and a second load current connection on a second surface facing away from the first surface;
wherein the first semiconductor switch is contact-connected to the second conductor track via the first load current connection;
wherein the second load current connection of the first semiconductor switch forms the second current connection area.

29. The power electronics module of claim 28, wherein the first signal connection area is part of the second conductor track.

30. The power electronics module of claim 28, further comprising:
a second semiconductor switch having
a first load current connection on a first surface; and
a second load current connection on a second surface facing away from the first surface, which second semiconductor switch rests on the first conductor track via the first load current connection and is electrically connected to the first conductor track;
wherein the second load current connection of the second semiconductor switch forms the third current connection area.

31. The power electronics module of one of claim 28, furthermore having
a third plate-shaped contact-making element formed in one piece and contact-connected to the second conductor track;
a plate-shaped electrical insulator, which is arranged between the second plate-shaped contact-making element and the third plate-shaped contact-making element and is physically connected to the second plate-shaped contact-making element and the third plate-shaped contact-making element and electrically insulates the second plate-shaped contact-making element and the third plate-shaped contact-making element from one another.

32. The power electronics module of claim 31, wherein the insulator is part of the plastic compound.

33. The power electronics module of one of claim 31, further comprising a fourth plate-shaped contact-making element formed in one piece and contact-connected to the first conductor track.

34. The power electronics module of one of claim 28, the circuit carrier further comprising a cooling layer for cooling the module on a surface facing away from the conductor tracks.

35. The power electronics module of claim 20, wherein the first plate-shaped contact-making element is formed as a stamped and bent part that is bent from the first electrical contact plane toward the second electrical contact plane.

36. The power electronics module of claim 20, the first plate-shaped contact-making element further comprising:
at least one connection lug being part of the first contact-making portion, that is bent away from the main plane of the first contact-making portion in the direction of the first electrical contact plane; and/or
at least one connection lug being part of the second contact-making portion, that is bent away from the main plane of the second contact-making portion in the direction of the second electrical contact plane.

37. The power electronics module of claim 20, wherein the first signal connecting element is in the form of a bonding wire or a bonding tape.

38. An inverter, having:
a housing;
power electronics modules of one of claim 20, which are arranged in the housing.
